(19) United States
(12) Patent Application Publication
(10) Pub. No.: US 2024/0204392 A1
(43) Pub. Date: Jun. 20, 2024

(54) WAVEGUIDE ANTENNA AND MOTOR VEHICLE

(71) Applicant: HELLA GmbH & Co. KGaA, Lippstadt (DE)

(72) Inventors: Christian SIEVERS, Lippstadt (DE); Dietmar PHILIPP, Erwitte (DE)

(73) Assignee: HELLA GmbH & Co. KGaA, Lippstadt (DE)

(21) Appl. No.: 18/593,891

(22) Filed: Mar. 2, 2024

Related U.S. Application Data
(63) Continuation of application No. PCT/EP2022/073296, filed on Aug. 22, 2022.

(30) Foreign Application Priority Data
Sep. 2, 2021 (DE) 10 2021 122 758.5

(51) Int. Cl. H01Q 1/32; H01Q 1/02; H01Q 1/38; H05K 1/02

(52) U.S. Cl. CPC H01Q 1/32; H01Q 1/02; H01Q 1/38; H05K 1/0203; H05K 1/0243; H05K 2201/10098

(57) ABSTRACT

A waveguide antenna for a motor vehicle, the waveguide antenna having a printed circuit board, an at least partially hollow antenna body with at least one opening, a connector, and a cover body. The cover body at least partially covers the at least one opening of the antenna body, wherein the printed circuit board, the antenna body, the connector, and the cover body are arranged stacked along a stacking direction. The connector includes at least one connecting element and the at least one connecting element connects the connector, the printed circuit board, the antenna body, and the cover body to one another. A motor vehicle having at least one waveguide antenna is also provided.

This nonprovisional application is a continuation of International Application No. PCT/EP2022/073296, which was filed on Aug. 22, 2022, and which claims priority to German Patent Application No. 10 2021 122 758.5, which was filed in Germany on Sep. 2, 2021, and which are both herein incorporated by reference.

### BACKGROUND OF THE INVENTION

### Field of the Invention

The present invention relates to a waveguide antenna, in particular for radar sensors, for a motor vehicle. The invention furthermore relates to a motor vehicle with a waveguide antenna.

### Description of the Background Art

In addition to very powerful signal generation and low-loss antenna technology, another important consideration in the development of waveguide antennas, in particular for radar sensors, for motor vehicles, is the smallest possible space requirement for the overall sensor.

The waveguide antennas and sensors that currently are publicly known generally have thermal problems, for example due to the heat generation of the related high-performance radar integrated circuits (MMIC) and/or problems with unwanted reflections in the sensor housing of the high-frequency signals emitted by the sensor, the motor vehicle, and/or other sources. In the prior art, efforts are made to solve the problems that occur by additional measures and/or separate components such as heat sinks and absorbers.

The high-performance radar circuits that are used are generally very sensitive to radiated interference from other interference sources. Conventional waveguide antennas for automotive applications generally cannot guarantee the requisite shielding and an EMC protection associated therewith, with the result that additional components such as tuner boxes become necessary.

### SUMMARY OF THE INVENTION

It is therefore an object of the present invention to remedy or to at least partially remedy the above-described disadvantages in the prior art. In particular, it is an object of the invention to provide a waveguide antenna with which a smaller space requirement, simplified assembly, improved cooling, and/or improved EMC protection are made possible especially simply. In particular, it is also the object of the invention to provide a motor vehicle having a corresponding waveguide antenna.

Features that are described in connection with the waveguide antenna according to the invention also apply in connection with the motor vehicle according to the invention and vice versa in each case, so mutual reference is or can always be made with regard to the disclosure of the individual aspects of the invention.

According to a first aspect of the invention, the object is attained by a waveguide antenna for a motor vehicle. The waveguide antenna can have a printed circuit board, an at least partially hollow antenna body with at least one opening, a connector, and a cover body. The cover body at least partially covers the at least one opening of the antenna body, wherein the printed circuit board, the antenna body, the connector, and the cover body are arranged stacked along a stacking direction, wherein the connector includes at least one connecting element and the at least one connecting element connects the connector, the printed circuit board, the antenna body, and the cover body to one another.

The waveguide antenna can be designed in a sandwich construction. The claimed components of the waveguide antenna—printed circuit board, antenna body, connector, and cover body—are arranged on one another along a stacking direction and fastened to and/or onto one another. The printed circuit board can have at least one chip, in particular a high-performance radar integrated circuit. The at least one chip can be, for example, a heat source. The chip can include transmitting and/or receiving units, wherein the transmitting and/or receiving units can be designed such that radio waves, in particular high-frequency radar waves, are transmitted into the antenna body and/or received from the antenna body. The transmitting and/or receiving units are connected to the at least one chip in a data-communicating manner. The transmitting and receiving units can be integrated in the chip, in particular in an MMIC component. This chip can be arranged centrally under the antenna body waveguide. The transmitting and receiving units preferably can be designed to be separate from the chip and be connected thereto in a data-communicating manner, for example by means of two-dimensional copper structures. The chip can be arranged on the antenna body side of the printed circuit board. Depending on the application, however, the chip can also be arranged on the underside of the printed circuit board.

The at least partially hollow antenna body should be understood as a kind of box, for example, and can be formed of at least of walls surrounding the interior space and a bottom, so that a cavity is created in the antenna body. The cavity can preferably be designed to be at least partially open on a cover side. This opening is at least partially covered by the cover body. The cover body preferably additionally can have entry and exit openings for radio waves. An antenna body designed in such a manner is designed advantageously for relaying, for propagation, for transmitting, and/or for receiving radio waves, in particular high-frequency radar waves. The cover body can be made of metal or a plastic. A hollow antenna body can be adapted and/or produced especially advantageously for the relaying, the propagation, the transmitting, and/or the receiving of radio waves.

The claimed components of the waveguide antenna can be connected by means of the at least one connector. Within the scope of the invention, a connecting should be understood as a fastening, a frictional and/or interlocking locking to one another and/or onto one another, and/or a securing of position relative to one another. The connector is arranged stacked along a stacking direction with the other claimed components, and has at least one connecting element. The connecting element with the connector may permit a connection of the printed circuit board, the antenna body, and the cover body.

A waveguide antenna designed in such a manner is especially advantageous, since assembly of the components of the waveguide antenna is made possible especially simply.

It is likewise advantageous when the components of the waveguide antenna have at least one centering device such as, e.g., posts and bores that arrange the component parts in the correct positions relative to one another during assembly.

The waveguide antenna, in particular the connector, can include an absorber, in particular wherein the antenna body and/or the cover body are arranged between the absorber and the printed circuit board. The connector according to the improvement includes an absorber and/or is itself designed as an absorber. An absorber should be understood within the scope of the invention as a device for at least partial shielding and/or absorption of radio waves, in particular high-frequency radar waves. The absorber function can preferably be made possible by means of metal and/or carbon particles in the absorber and/or the connector. Preferably, the metal and/or carbon particles can be incorporated in a thermoplastic plastic of the absorber and/or of the connector. The absorber and/or the connector permit a damping effect against radio waves, and thus a shielding from unwanted interference signals and/or a shielding and/or avoidance of reflections of radio waves. Preferably, the absorber and/or the connector with absorber can form the outermost and/or topmost layer and/or component along the stacking direction of the waveguide antenna in order to permit an advantageous absorption and/or shielding. A waveguide antenna designed in such a manner is especially advantageous, since assembly and EMC protection are made possible especially simply.

The waveguide antenna can includes a cooling and EMC device, wherein the cooling and EMC device is connected in a thermally conductive manner to the printed circuit board and/or the antenna body, in particular wherein the cooling and EMC device is arranged at least partially between the printed circuit board and the antenna body. In a simple, preferred embodiment, the cooling and EMC device is designed as a metal sheet or a metal plate. Advantageously, the cooling and EMC device can include cooling fins or other cooling devices, in particular for enlarging a heat transfer surface of the cooling and EMC device. The cooling and EMC device is preferably connected in a thermally conductive manner to the above-described chip of the printed circuit board and thus advantageously permits cooling of the chip, which generally represents the primary heat source. The cooling and EMC device can preferably include metal and/or carbon particles for improved shielding against radio waves.

The cooling and EMC device can furthermore be metallically coated in order to improve the shielding effect.

In one functional unit, the cooling and EMC device advantageously permits cooling of the printed circuit board and EMC shielding of the printed circuit board against, e.g., interference signals and/or reflections.

The waveguide antenna can include a separate EMC device that is arranged between the connector and the cover body, in particular wherein the EMC device entirely or partially overlaps the printed circuit board. Preferably, the EMC device is connected to the ground of the printed circuit board and/or the component holder in an electrically conductive manner. A waveguide antenna designed in such a manner is especially advantageous, since an EMC device is likewise advantageously made possible when no cooling device is necessary. Alternatively, the separate EMC device can be arranged and installed in addition to the above-described cooling and EMC device.

The antenna body can overlap or essentially overlaps the entire printed circuit board, in particular wherein the antenna body is electrically connected to a ground of the printed circuit board. The antenna body can be electrically connected to the ground of the printed circuit board at the edge of the printed circuit board. The ground of the printed circuit board preferably is designed as a copper layer of the printed circuit board. A waveguide antenna designed in such a manner is especially advantageous, since the antenna body can therefore itself take on the function of an EMC device. The antenna body can advantageously be made at least partially of metal, as described later, for this purpose.

The antenna body can be connected directly to the printed circuit board in a thermally conductive manner. According to this embodiment, the antenna body can additionally or alternatively serve as a cooling device for the printed circuit board. Preferably, it is thus connected in a thermally conductive manner directly to a chip, in particular MMIC, of the printed circuit board. Furthermore, a heat transfer element for compensating for surface irregularities and/or for improving the heat transfer is preferably arranged between the printed circuit board and the antenna body.

The connector, the absorber, the cover body, the cooling and EMC device, the antenna body, and/or the printed circuit board can be at least partially adhesive-bonded to one another. An additional adhesive bonding, in particular an electrically conductive and/or radio-wave-conductive adhesive bonding, advantageously permits a supplementary fastening and/or securing of position to the connector and the at least one connecting element. Preferably, individual claimed components of the waveguide antenna are adhesive-bonded to one another in pairs and/or all claimed components, in particular the neighboring components in each case, are adhesive-bonded to each adjacent component. An adhesive bonding advantageously permits supplementary retention and/or securing of position of the claimed components of the waveguide antenna with simple means.

The connector integrally, in particular monolithically, can include a multiplicity of connecting elements and/or that the at least one connecting element includes a free end with one deformation each, wherein the deformation connects the connector, the absorber, the cover body, the cooling and EMC device, the antenna body, and/or the printed circuit board to one another. The multiplicity of connecting elements preferably are designed as one piece with the connector. By way of example, the connector is produced as an injection molded part, in particular of plastic, wherein the connecting elements are designed as one piece with the connector. By way of example, the connecting elements can each be designed as a dome, pin, stud, post, and/or another form. Within the framework of producing the waveguide antenna, the connecting elements are deformed at a free end in order to create a deformation. The deformation in turn permits a connection of the connector, the absorber, the cover body, the cooling and EMC device, the antenna body, and/or the printed circuit board to one another. The deformation preferably is accomplished by a plasticization of the free ends and a subsequent hardening. The deformation preferably is accomplished by means of heat staking and/or ultrasonic staking. Alternatively or in addition, the free ends of the connecting elements can be spread apart, bent over, and/or otherwise deformed for the purpose of connection. A deformation of the connecting elements to connect the connector, the absorber, the cover body, the cooling and EMC device, the antenna body, and/or the printed circuit board represents an especially advantageous connection, since low cost, time, materials, and space requirements are created.

The at least one connecting element can extend through mutually aligned connecting holes in the connector, the cover body, the cooling and EMC device, the antenna body, and/or the printed circuit board, in particular along the stacking direction. It is especially preferred when the at least one connecting element extends through aligned connecting holes in the claimed components of the waveguide antenna. The claimed components are arranged stacked along a stacking direction, as described above. The connecting element according to the invention is, for example, inserted opposite the stacking direction from one side through the stacked components and deformed and/or otherwise fastened in accordance with the preceding paragraph on an opposite side in order to permit the connection according to the invention. A waveguide antenna designed in such a manner is especially advantageous, since the connection and simultaneous arrangement of the components of the waveguide antenna relative to one another is made possible especially simply.

The waveguide antenna, in particular the antenna body, can include at least one fastener, wherein the at least one fastener is designed to fasten the waveguide antenna to a component holder of the motor vehicle. Preferably, the waveguide antenna is fastened in and/or to a plastic housing that protects the sensor electronics from environmental influences. The housing, in turn, preferably has fastening elements for installation in the motor vehicle. The at least one fastener is designed, for example, as a lug with a hole for a screw connection. Preferably, the waveguide antenna includes a multiplicity of fasteners, in particular three. Alternatively or in addition, the at least one fastener is designed as a clamped and/or snap-in fastening. Preferably, a fastening of the waveguide antenna to a component holder of the motor vehicle by means of the at least one fastener is provided. A component holder of a motor vehicle can additionally be designed as a heat sink in a combination of functions.

The printed circuit board can include at least one transmitting unit and/or at least one receiving unit, wherein the at least one transmitting unit and/or the at least one receiving unit are designed to transmit signals into and/or to receive signals from the antenna body. As described above, the printed circuit board preferably has at least one chip, in particular a high-performance radar integrated circuit. According to the improvement described, the waveguide antenna, in particular the chip and/or the printed circuit board, include at least one transmitting and/or receiving unit. The transmitting and/or receiving units can be designed such that radio waves, in particular high-frequency radar waves, are transmitted into the antenna body and/or received from the antenna body. The transmitting and/or receiving units preferably are connected to the at least one chip in a data-communicating manner. The antenna body preferably has a recess for the at least one transmitting unit and/or at least one receiving unit. Preferably, the at least one transmitting unit and/or at least one receiving unit are arranged on a bottom section of the antenna body, and the cover body is arranged on an opposite top of the antenna body. The at least one transmitting unit and the at least one receiving unit preferably are designed to be separate and/or spaced apart from one another. Preferably, the at least one transmitting unit and/or at least one receiving unit are arranged on opposite sides from the high-performance radar integrated circuit on the printed circuit board. The at least one transmitting unit and/or at least one receiving unit preferably are designed to transmit and/or receive radio waves, in particular high-frequency radar waves. A waveguide antenna designed in such a manner is designed especially advantageously for transmitting and receiving radio waves, in particular high-frequency radar waves, since assembly, cooling, and EMC protection of the waveguide antenna are made possible especially simply with simple and economical means.

The cooling and EMC device can have at least one recess for the at least one transmitting unit and/or the at least one receiving unit. For better transmission and reception of the radio waves, it is advantageous when the cooling and EMC device has at least one recess for the at least one transmitting unit and/or the at least one receiving unit. The at least one recess is preferably designed as a penetrating and/or planar recess in and/or through the cooling and EMC device in the region of the at least one transmitting unit and/or at least one receiving unit. The at least one recess advantageously permits the transmitting and/or the receiving of radio waves, wherein an advantageous EMC shielding of the surrounding regions of the at least one transmitting unit and/or at least one receiving unit, in particular the printed circuit board, is made possible at the same time.

The waveguide antenna can have at least one thermally conductive heat transfer element between the printed circuit board and the antenna body, between the printed circuit board and the cooling and EMC device, and/or between the printed circuit board and the component holder of the motor vehicle. A thermally conductive heat transfer element arranged in such a manner is especially advantageous, since an improved heat transfer between the printed circuit board and the component holder of the motor vehicle, between the printed circuit board and the cooling and EMC device, and/or between the printed circuit board and the antenna body is made possible as a result. As described above, a fastening of the waveguide antenna to a component holder of the motor vehicle is preferably provided by means of the at least one fastener. The component holder of a motor vehicle can additionally be designed as a heat sink in a combination of functions. For example, a component holder is arranged on a first side, in particular underside, of the printed circuit board, and the antenna body is arranged on a second, opposite side, in particular top, of the printed circuit board. Consequently, a dissipation of the heat from the printed circuit board, in particular from the chip as a heat source of the printed circuit board, is advantageously made possible on two sides.

The antenna body and/or the cover element can have a metal layer at least on the surface, in particular wherein the antenna body and/or the cover element is designed and made from a plastic. Preferably, the antenna body and/or the cover element is made of metal. To save weight and costs, the antenna body and/or the cover element can alternatively be made of plastic and have, for example, a 1 to 2 μm metal layer on the surface. The metal layer preferably is vapor-deposited on the antenna body and/or the cover element. An antenna body and/or cover element designed in such a manner are especially preferably suitable for use as waveguide antenna components, since the relaying, propagation, the transmission and/or the reception of radio waves, in particular high-frequency radar waves, is advantageously made possible.

The connector, the absorber, the cover body, the cooling and EMC device, the antenna body, and/or the printed circuit board can be planar in design and can have a base area, in particular a base area of equal size, orthogonal to the stacking direction. The individual components, the connector, the absorber, the cover body, the cooling and EMC device, the antenna body, and/or the printed circuit board, have a planar or essentially planar design. The phrase “X or essentially X” should be understood within the scope of the invention as a possible, slight deviation, for example on account of production tolerances, material and/or process properties, without changing the underlying, intended function of the feature. Clearly, the extent of the components in two spatial directions is significantly larger than in the third spatial direction. The third spatial direction corresponds here to the stacking direction of the waveguide antenna. The base area of the claimed components preferably is equal in size or essentially equal in size. The base area extends in the plane of the first and second spatial directions. A waveguide antenna designed in such a manner permits an advantageous arrangement of the claimed components in a stacked arrangement along the stacking direction. A waveguide antenna designed in such a manner has an especially efficient utilization of space.

The waveguide antenna can include a body, in particular a housing, wherein the body at least partially encloses the connector, the absorber, the cover body, the cooling and EMC device, the antenna body, and/or the printed circuit board, in particular wherein the body is connected in a thermally conductive manner to the connector, the absorber, the cover body, the cooling and EMC device, the antenna body, and/or the printed circuit board. A body and/or a housing represent advantageous improvements of the waveguide antenna according to the invention, since the body or the housing permits, for example, protection from dirt, environmental influences, and/or interference signals.

The object is also attained by a motor vehicle having at least one waveguide antenna, wherein the waveguide antenna is designed according to the first aspect.

All the advantages already described with respect to the waveguide antenna according to the first aspect of the invention arise in the motor vehicle described.

The motor vehicle can include a component holder for fastening the waveguide antenna, in particular wherein the component holder includes a heat sink.

Further scope of applicability of the present invention will become apparent from the detailed description given hereinafter. However, it should be understood that the detailed description and specific examples, while indicating preferred embodiments of the invention, are given by way of illustration only, since various changes, combinations, and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 shows in a perspective view, a motor vehicle with a waveguide antenna on a component holder,

FIG. 2 shows a waveguide antenna on a component holder in a sectional view,

FIG. 3 shows a waveguide antenna in an exploded view,

FIG. 4 shows another waveguide antenna in an exploded view, and

FIG. 5 shows a waveguide antenna in a perspective view from below.

### DETAILED DESCRIPTION

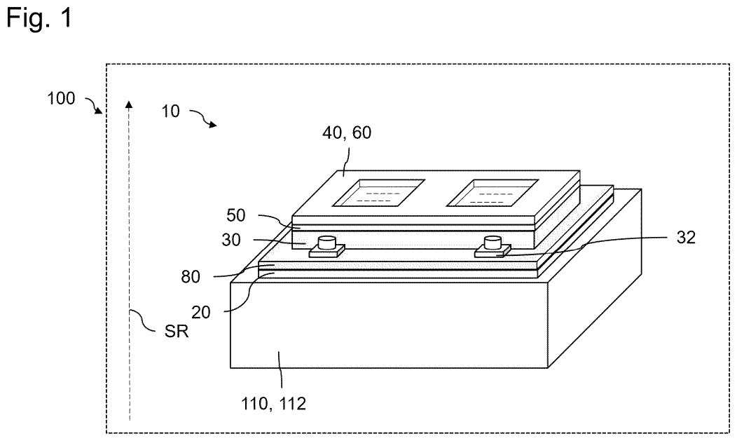

In FIG. 1, a motor vehicle 100 with a waveguide antenna 10 on a component holder 110 of the motor vehicle 100 is schematically shown in a perspective view. The motor vehicle 100 includes a component holder 110 for fastening the waveguide antenna 10, wherein the component holder 110 includes a heat sink 112. The waveguide antenna 10 has a printed circuit board 20, an at least partially hollow antenna body 30 with at least one opening, a connector 40, and a cover body 50. The cover body 50 at least partially covers the at least one opening of the antenna body 30. The printed circuit board 20, the antenna body 30, the connector 40, and the cover body 50 are arranged stacked along a stacking direction SR. The arrow for the stacking direction SR points in the direction of a top of the waveguide antenna 10. The connector 40 includes at least one connecting element 42, and the at least one connecting element 42 connects the connector 40, the printed circuit board 20, the antenna body 30, and the cover body 50 to one another. The connector 40 includes an absorber 60. The antenna body 30 and the cover body 50 are arranged between the absorber 60 and the printed circuit board 20. The waveguide antenna 10 additionally includes a cooling and EMC device 80, wherein the cooling and EMC device 80 is connected in a thermally conductive manner to the printed circuit board 20 and the antenna body 30. The cooling and EMC device 80 is arranged at least partially between the printed circuit board 20 and the antenna body 30. The antenna body 30 includes a multiplicity of fasteners 32, wherein two are visible. The fasteners 32 are designed to fasten the waveguide antenna 10 to the component holder 110 of the motor vehicle 100.

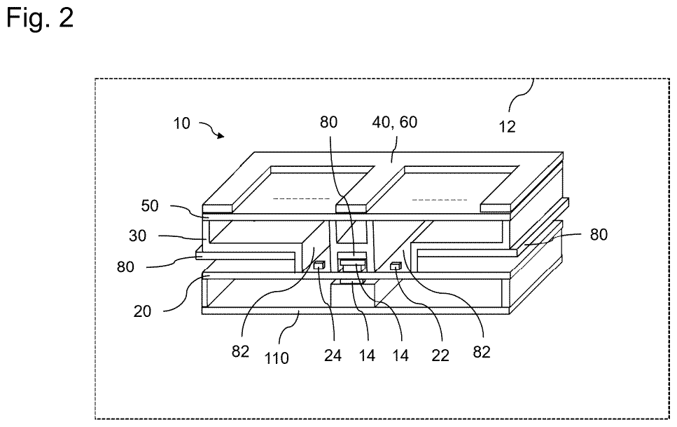

In FIG. 2, a waveguide antenna 10 on a component holder 110 is shown in a sectional view. The printed circuit board 20 includes a transmitting unit 22 and a receiving unit 24, wherein the transmitting unit 22 and the receiving unit 24 accordingly are designed to transmit signals into or to receive signals from the antenna body 30. The cooling and EMC device 80 has a recess 82 in each case for the transmitting unit 22 and the receiving unit 24. The waveguide antenna 10 additionally has one thermally conductive heat transfer element 14 each between the printed circuit board 20 and the component holder 110 of the motor vehicle 100 as well as between the printed circuit board 20, here a chip on the printed circuit board 20, and the cooling and EMC device 80. The waveguide antenna 10 includes a body 12 in the form of a housing. The body 12 at least partially encloses the connector 40, the absorber 60, the cover body 50, the cooling and EMC device 80, the antenna body 30, and the printed circuit board 20.

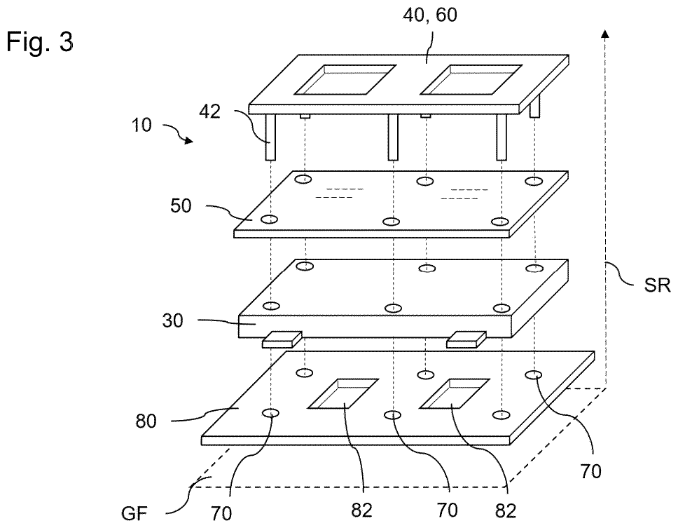

In FIG. 3, a waveguide antenna 10 is shown in an exploded view. The connector 40 integrally and monolithically includes a multiplicity of connecting elements 42, here six connecting elements 42, wherein only one connecting element 42 is labeled with a reference symbol for improved clarity. The connecting elements 42 each have one free end with one deformation 44 each. The multiplicity of connecting elements 42 connects the connector 40, the absorber 60, the cover body 50, the cooling and EMC device 80, the antenna body 30, and the printed circuit board 20 to one another. The multiplicity of connecting elements 42 extends through mutually aligned connecting holes 70 in the cover body 50, the cooling and EMC device 80, and the antenna body 30 along the stacking direction SR. For improved clarity, not all connecting holes 70 are labeled with a reference symbol. The cooling and EMC device 80 has a recess 82 in each case for the transmitting unit 22 (not shown) and the receiving unit 24. The connector 40, the absorber 60, the cover body 50, the cooling and EMC device 80, and the antenna body 30 are planar in design, and have a base area GF of essentially equal size orthogonal to the stacking direction SR. The connecting elements 42 according to the invention are inserted opposite the stacking direction SR from an upper side through the stacked components 50, 30, 80 and deformed on an opposite side in order to permit the connection according to the invention. A waveguide antenna 10 designed in such a manner is especially advantageous, since the connection and simultaneous arrangement of the components 50, 30, 80 of the waveguide antenna 10 relative to one another is made possible especially simply.

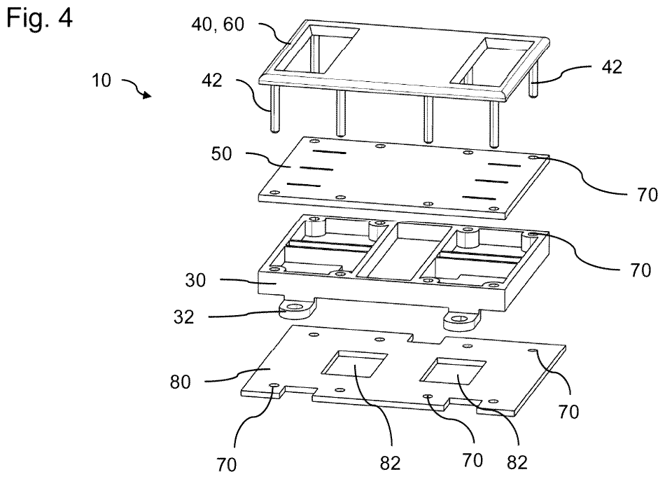

In FIG. 4, another waveguide antenna 10 is shown in an exploded view. Beyond the remarks regarding the waveguide antenna 10 in FIG. 3, in FIG. 4 the design of the antenna body 30 is represented at least partially as a hollow antenna body 30. The antenna body 30 is formed of walls surrounding the interior space and a bottom, so that a cavity is created in the antenna body 30. The cavity is designed to be at least partially open on a top cover side. This opening is at least partially covered by the cover body 50. The cover body 50 additionally has entry and exit openings in the form of slots for radio waves. The cover body 50 is can be made of metal. A hollow antenna body 30 can be adapted and/or produced especially advantageously for the relaying, the propagation, the transmitting, and/or the receiving of radio waves. The cooling and EMC device 80 has recesses for the fasteners 32 of the antenna body 30.

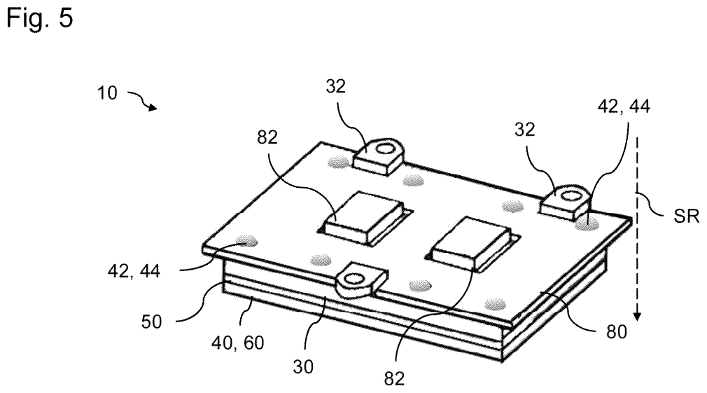

In FIG. 5, a waveguide antenna 10 is shown in a perspective view from below. The connecting elements 42 each have one free end with one deformation 44 each. The connecting elements 42 according to the invention are inserted for this purpose opposite the stacking direction SR from an upper side that is not visible through the stacked components 50, 30, 80 and deformed on the underside that is shown in order to permit the connection according to the invention. The deformations 44 of the connecting elements 42 permit a connection of the connector 40, the absorber 60, the cover body 50, the cooling and EMC device 80, and the antenna body 30 to one another. The cooling and EMC device 80 has in each case a recess 82 for the transmitting unit 22 and the receiving unit 24 (not shown), wherein the antenna body 30 projects through the cooling and EMC device 80. The connecting elements 42 extend along the stacking direction SR through mutually aligned connecting holes 70 in the cover body 50, the cooling and EMC device 80, and the antenna body 30.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A waveguide antenna for a motor vehicle, the waveguide antenna comprising:
a printed circuit board;
an at least partially hollow antenna body with at least one opening;
a connector; and
a cover body that at least partially covers the at least one opening of the antenna body,
wherein the printed circuit board, the antenna body, the connector, and the cover body are arranged stacked along a stacking direction, and
wherein the connector includes at least one connecting element the connects the connector, the printed circuit board, the antenna body, and the cover body to one another.

2. The waveguide antenna according to claim 1, wherein the waveguide antenna or the connector includes an absorber, or wherein the antenna body and/or the cover body are arranged between the absorber and the printed circuit board.

3. The waveguide antenna according to claim 1, wherein the waveguide antenna includes a cooling and EMC device, wherein the cooling and EMC device is connected in a thermally conductive manner to the printed circuit board and/or the antenna body, and wherein the cooling and EMC device is arranged at least partially between the printed circuit board and the antenna body.

4. The waveguide antenna according to claim 1, wherein the waveguide antenna includes a separate EMC device that is arranged between the connector and the cover body, and wherein the EMC device entirely or partially overlaps the printed circuit board.

5. The waveguide antenna according to claim 1, wherein the antenna body overlaps the printed circuit board, and wherein the antenna body is electrically connected to a ground of the printed circuit board.

6. The waveguide antenna according to claim 1, wherein the antenna body is connected directly to the printed circuit board in a thermally conductive manner.

7. The waveguide antenna according to claim 1, wherein the connector, the absorber, the cover body, the cooling and EMC device, the antenna body, and/or the printed circuit board are at least partially adhesive-bonded to one another.

8. The waveguide antenna according to claim 1, wherein the connector integrally or monolithically, includes a multiplicity of connecting elements and/or wherein the at least one connecting element includes a free end with one deformation each, the deformation connecting the connector, the absorber the cover body, the cooling and EMC device, the antenna body, and/or the printed circuit board to one another.

9. The waveguide antenna according to claim 1, wherein the at least one connecting element extends through mutually aligned connecting holes in the connector, the cover body, the cooling and EMC device, the antenna body and/or the printed circuit board opposite the stacking direction.

10. The waveguide antenna according to claim 1, wherein the waveguide antenna or the antenna body includes at least one fastener, wherein the at least one fastener is designed to fasten the waveguide antenna to a component holder of the motor vehicle.

11. The waveguide antenna according to claim 1, wherein the printed circuit board includes at least one transmitter and/or at least one receiver, wherein the at least one transmitter and/or the at least one receiver are designed to transmit signals into and/or to receive signals from the antenna body.

12. The waveguide antenna according to claim 11, wherein the cooling and EMC device has at least one recess for the at least one transmitter and/or the at least one receiver.

13. The waveguide antenna according to claim 1, wherein the waveguide antenna has at least one thermally conductive heat transfer element between the printed circuit board and the antenna body, between the printed circuit board and the cooling and EMC device, or between the printed circuit board and the component holder of the motor vehicle.

14. The waveguide antenna according to claim 1, wherein the antenna body has a metal layer at least on the surface, and wherein the antenna body is made from a plastic.

15. The waveguide antenna according to claim 1, wherein the connector, the absorber, the cover body, the cooling and EMC device, the antenna body, and/or the printed circuit board are planar in design and have a base area or a base area of equal size, orthogonal to the stacking direction.

16. The waveguide antenna according to claim 1, wherein the waveguide antenna further comprises a body having a housing, wherein the body at least partially encloses the connector, the absorber, the cover body, the cooling and EMC device, the antenna body, and/or the printed circuit board, or wherein the body is connected in a thermally conductive manner to the connector, the absorber, the cover body, the cooling, the EMC device, the antenna body, and/or the printed circuit board.

17. A motor vehicle comprising at least one waveguide antenna, wherein the at least one waveguide antenna is the waveguide antenna according to claim 1.

18. The motor vehicle according to claim 17, wherein the motor vehicle comprises a component holder for fastening the waveguide antenna, and wherein the component holder includes a heat sink.
